(19) United States
(12) Patent Application Publication
(10) Pub. No.: US 2008/0048217 A1
(43) Pub. Date: Feb. 28, 2008

(54) Semiconductor device and method of fabricating the same

(75) Inventors: Ki-Chul Kim, Suwon-si (KR); Hwa-Sung Rhee, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/790,364

(22) Filed: Apr. 25, 2007

(30) Foreign Application Priority Data
Aug. 25, 2006 (KR) 10-2006-80975

(51) Int. Cl. H01L 29/76; H01L 21/336

(52) U.S. Cl. 257/288; 438/197; 257/E29.226; 257/E21.409

(57) ABSTRACT

A semiconductor device may include a gate pattern formed on a semiconductor substrate. At least one impurity region may be formed in the semiconductor substrate such that at least a portion of the at least one impurity region is disposed under the gate pattern. An epitaxial growth layer may be formed on the at least one impurity region. The epitaxial growth layer may include a first epitaxial growth portion spaced apart from the gate pattern and a second epitaxial growth portion extending toward the gate pattern from the first epitaxial growth portion.

### PRIORITY STATEMENT

This U.S. non-provisional application claims the benefit of priority to Korean Patent Application No. 10-2006-80975, filed Aug. 25, 2006, in the Korean Intellectual Property Office (KIPO), the contents of which are hereby incorporated herein by reference in their entirety.

### BACKGROUND

1. Field

Example embodiments relate to a semiconductor device and a method of fabricating the same, for example, a Metal-Oxide-Semiconductor (MOS) transistor and a method of fabricating the same.

2. Description of the Related Art

To meet the demand fro semiconductor devices having higher speed and higher integration density, extensive work is being carried out to overcome limitations in miniaturization of semiconductor devices. For example, in a Metal-Oxide-Semiconductor (MOS) transistor, which may be used as a switching device of a semiconductor device, the drain current and the switching characteristic of the MOS transistor may be directly influenced by carrier mobility in a channel region of the MOS transistor. Accordingly, the carrier mobility may be considered as an essential factor in development of a higher-performance MOS transistor.

Recently, various methods have been proposed to improve channel carrier mobility. For example, methods for improving the channel carrier mobility may include applying a stress to the channel region of the MOS transistor so that the channel region may be converted into a strained channel region.

According to a conventional method of fabricating a MOS transistor having a strained channel layer, a silicon substrate may be etched to form a recess region on opposite sides of a gate electrode, and a silicon-germanium (SiGe) layer may be formed in the recess region using an epitaxial growth technique. As a result, the SiGe layer may generate horizontal compressive stress in a crystal lattice of a silicon substrate disposed under the gate electrode to form a compressive strained channel layer. Accordingly, hole mobility in the compressive strained channel layer may be increased to improve switching speed of the MOS transistor.

According to a conventional method of fabricating a MOS transistor using a SiGe layer as source and drain regions, a gate electrode may be formed on a semiconductor substrate, and a barrier oxide layer may be formed covering the gate electrode. The semiconductor substrate may be anisotropically etched using the barrier oxide layer as an etch mask to form recessed regions in the semiconductor substrate on opposite sides of the gate electrode. SiGe layers may be formed in the recessed regions using an epitaxial growth technique, and impurities may be implanted into the SiGe layer to form lightly doped drain (LDD) type source and drain regions.

If the semiconductor substrate is a silicon substrate, the SiGe layers may apply a stress to the channel region under the gate electrode to provide a strained channel layer. However, the depth of the recessed regions may be increased to increase the strained effect. For example, the depth of the SiGe layers formed on opposite sides of the gate electrode may be increased. In this case, junction leakage current of the source and drain regions formed in the SiGe layers may be increased. This is because if the SiGe layers are formed using an epitaxial growth technique, crystal defects may be generated at interfaces between SiGe layers grown laterally and vertically on sidewalls and bottoms of the recessed regions, and the source and drain regions may be formed in the SiGe layers having the crystal defects. As a result, it may be difficult to increase the strained channel effect without degradation of the junction leakage current characteristics of the source and drain regions.

### SUMMARY

Example embodiments may provide a semiconductor device, and method of fabricating the same, that may increase a strained effect in a channel region without degradation of junction leakage current in source and drain regions.

In an example embodiment, a semiconductor device may include a gate pattern formed on a semiconductor substrate. At least one impurity region may be formed in the semiconductor substrate such that at least a portion of the impurity region is disposed under the gate pattern. An epitaxial growth layer may be formed on the at least one impurity region. The epitaxial growth layer may include a first epitaxial growth portion spaced apart from the gate pattern and a second epitaxial growth portion extending toward the gate pattern from the first epitaxial growth portion.

In an example embodiment, a method of fabricating a semiconductor device may include forming a gate pattern on a semiconductor substrate; forming a spacer on a sidewall of the gate pattern; forming at least one impurity region in the semiconductor substrate adjacent to the spacer; isotropically etching the impurity region to form a first recess region in the impurity region extending below the spacer; anisotropically etching the impurity region using the spacer and the gate pattern as etch masks to form a second recess region in the impurity region; and forming an epitaxial growth layer filling the first and second recess regions.

In an example embodiment, a method of fabricating a semiconductor device may include forming a gate pattern on a substrate; forming an impurity region in the substrate; etching the impurity region to create a first recess and a second recess, the second recess being deeper than the first recess and further from the gate pattern than the first recess; and filling the first and second recesses with an epitaxial layer.

In an example embodiment, a semiconductor device may include a gate pattern formed on a substrate. An epitaxial layer may be formed in the substrate. The epitaxial layer may include a first epitaxial portion formed in the substrate to a first depth, and a second epitaxial layer formed in the substrate to a second depth that is deeper than the first depth, the first epitaxial portion being closer to the gate pattern than the second epitaxial portion. Impurity regions may be formed under the first and second epitaxial portions.

### BRIEF DESCRIPTION OF THE DRAWINGS

Example embodiments will be described with reference to the accompanying drawings.

FIGS. 1 to 6 are cross-sectional views illustrating a method of fabricating a Metal-Oxide-Semiconductor (MOS) transistor according to an example embodiment.

FIGS. 7 to 9 are cross-sectional views illustrating a method of fabricating a MOS transistor according to another example embodiment.

### DESCRIPTION OF EXAMPLE EMBODIMENTS

Example embodiments will now be described more fully hereinafter with reference to the accompanying drawings. Example embodiments may, however, be embodied in different forms and should not be construed as limited to the example embodiments set forth herein. Rather, these example embodiments are provided so that this disclosure will be thorough, and will convey the scope to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

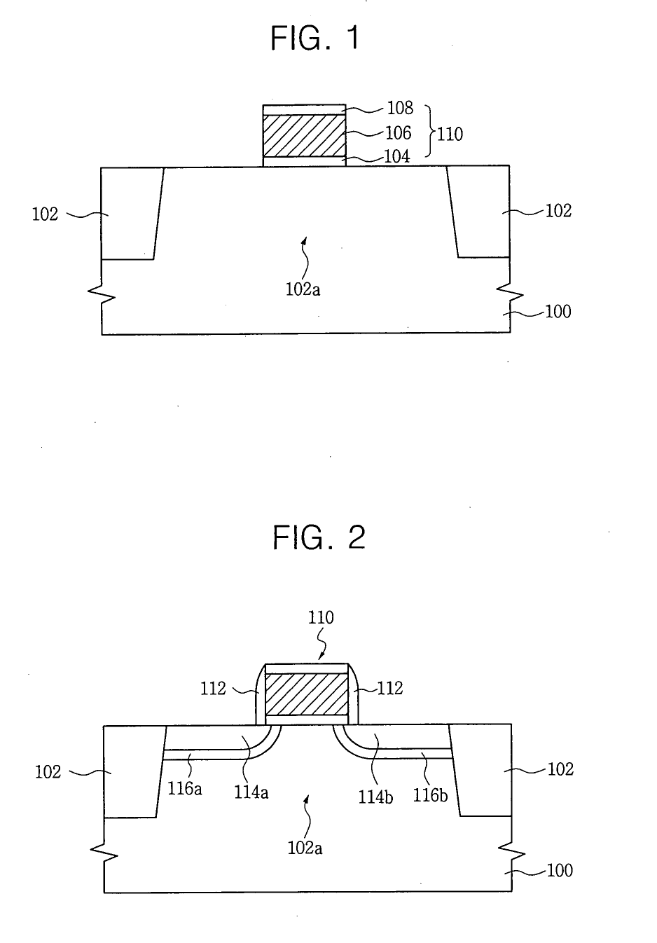

FIGS. 1 to 6 are cross-sectional views illustrating a method of fabricating a Metal-Oxide-Semiconductor (MOS) transistor according to an example embodiment.

Referring to FIG. 1, a semiconductor substrate 100 may be provided. The semiconductor substrate 100 may be a single crystal semiconductor substrate or a Silicon-On-Insulator (SOI) substrate having a single crystal semiconductor body layer. For example, the single crystal semiconductor substrate or single crystal semiconductor body layer may include a silicon (Si) layer, a germanium (Ge) layer, or a silicon-germanium (SiGe) layer.

An insulating region 102 may be formed in a predetermined (or, alternatively, a desired) region of the semiconductor substrate 100 to define an active region 102a. For example, the insulating region 102 may be formed using a conventional trench isolation technique. A gate insulating layer (not shown), a gate conductive layer (not shown), and a gate capping insulating layer (not shown) may be sequentially formed on the active region 102a. A gate pattern 110 may be formed over the active region 102a by patterning the gate capping insulating layer, the gate conductive layer, and the gate insulating layer. As a result, the gate pattern 110 may include a gate insulating layer pattern 104, a gate electrode 106, and a gate capping insulating pattern 108, which may be sequentially stacked.

Referring to FIG. 2, first impurity ions may be implanted into the active region using the gate pattern 110 as an ion implantation mask to form first and second lower-concentration impurity regions 114a and 114b on opposite sides of the gate pattern 110. The first impurity ions may have a different conductivity type from the semiconductor substrate 100.

A first spacer 112 may be formed on a sidewall of the gate pattern 110. For example, the first spacer 112 may be formed of a silicon oxide layer or a silicon nitride layer. A tilted ion implantation process may be applied to the substrate having the first spacer 112 to form first and second halo regions 116a and 116b surrounding the first and second lower-concentration impurity regions 114a and 114b, respectively. The halo regions 116a and 116b may be formed by implanting impurity ions having the same conductivity type as the semiconductor substrate 100. In another example embodiment, the ion implantation processes for forming the lower-concentration impurity regions 114a and 114b and the halo regions 116a and 116b may be performed after formation of the first spacers 112.

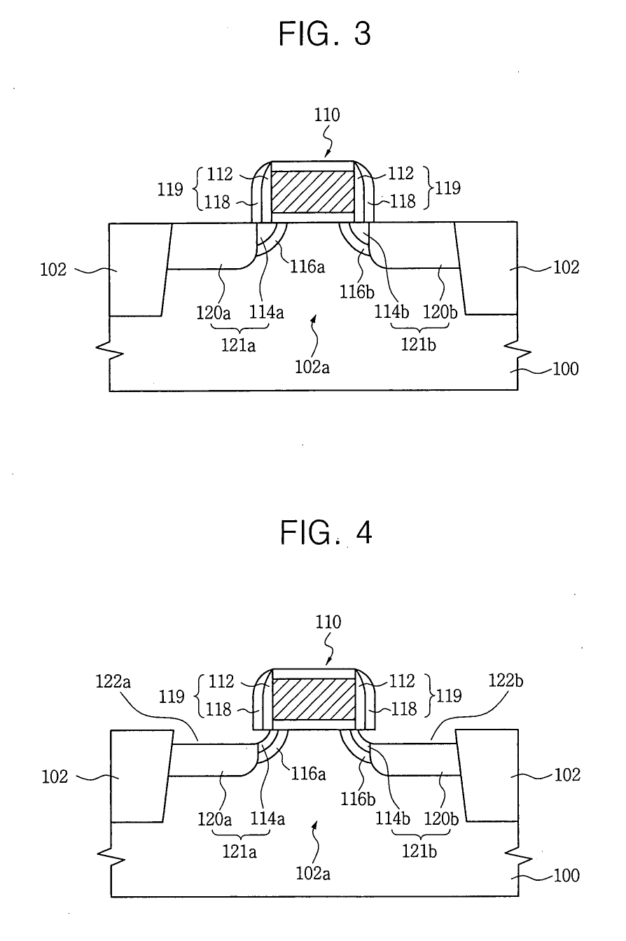

Referring to FIG. 3, a second spacer 118 may be formed on an outer sidewall of the first spacer 112. For example, the second spacer 118 may be formed of a silicon oxide layer or a silicon nitride layer. The first and second spacers 112 and 118 constitute a spacer 119. Second impurity ions may be implanted into the active region 102a using the gate pattern 110 and the spacer 119 as ion implantation masks to form first and second higher-concentration impurity regions 120a and 120b on opposite sides of the gate pattern 110. The second impurity ions may have the same conductivity type as the first impurity ions. The first and second higher-concentration impurity regions 120a and 120b may be formed to have a higher impurity concentration than the first and second lower-concentration impurity regions 114a and 114b. The higher-concentration impurity regions 120a and 120b may be formed to a deeper junction depth than the lower-concentration impurity regions 114a and 114b and the halo regions 116a and 116b. As a result, the remaining portion of the first and second lower-concentration impurity regions 114a and 114b may be located below the spacer 119.

The first lower-concentration impurity region 114a and the first higher-concentration impurity region 120a may constitute a first impurity region 121a (e.g., a source region), and the second lower-concentration impurity region 114b and the second higher-concentration impurity region 120b may constitute a second impurity region 121b (e.g., a drain region). The first and second impurity regions 121a and 121b may define a channel region in the active region 102a of the semiconductor substrate 100 underneath the gate pattern 110.

Referring to FIG. 4, a first etching process may be performed, using the gate capping insulating pattern 108 of the gate pattern 110 and the spacer 119 as etch masks, to form first recess regions 122a and 122b in the first and second higher concentration regions 120a and 120b and extending into the first and second lower-concentration impurity regions 114a and 114b below the spacer 119. For example, the first etching process may be performed using an isotropic etching technique. The first recess regions 122a and 122b may be formed to a shallow depth so that the halo regions 116a and 116b or the semiconductor substrate 100 may not be exposed. For example, the first recess regions 122a and 122b may be formed to a shallower depth than the lower-concentration impurity regions 114a and 114b by appropriately adjusting process conditions, for example, varying the etching gases and/or the etching time of the first etching process. For example, the first recess regions 122a and 122b may be formed to a depth of 100 Å to 300 Å, and for example, the first etching process may be performed using an etching gas including sulfur hexafluoride (SF₆).

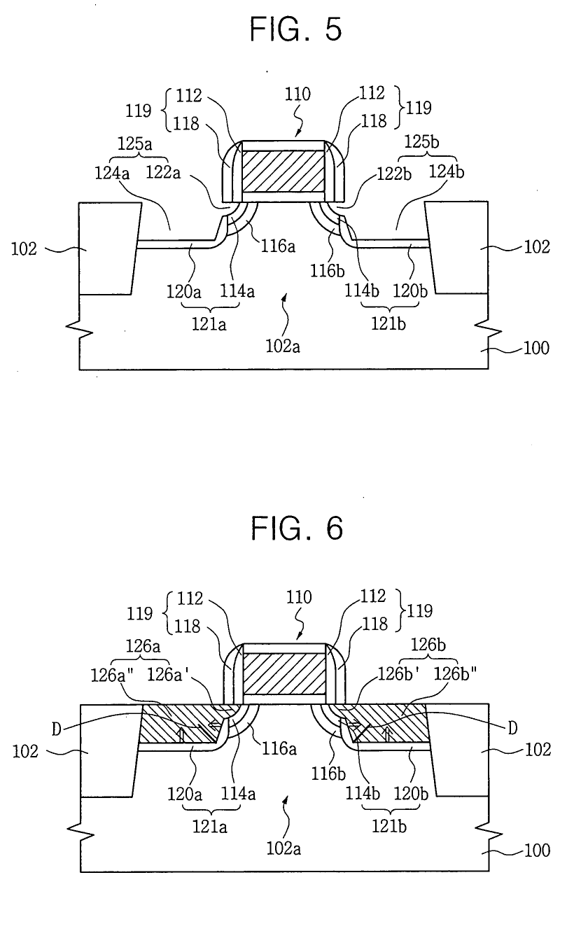

Referring to FIG. 5, a second etching process may be applied to the impurity regions 121a and 121b, using the gate capping insulating pattern 108 and the spacer 119 as etch masks, to form second recess regions 124a and 124b in the impurity regions 121a and 121b, respectively. For example, the second recess regions 124a and 124b may be formed by an anisotropic etching process. The second recess regions 124a and 124b may be formed to a depth so that the semiconductor substrate 100 under the impurity regions 121a and 121b may not be exposed and the first recess regions 122a and 122b may remain below the spacer 119.

The second recess regions 124a and 124b may be formed to be deeper than the first recess regions 122a and 122b. For example, the second recess regions 124a and 124b may be formed to a depth of 500 Å to 700 Å from a surface of the semiconductor substrate 100. The first and second recess regions 122a and 124a in the first impurity region 121a may constitute a source-side recess region 125a, and the first and second recess regions 122b and 124b in the second impurity region 121b may constitute a drain-side recess region 125b.

Referring to FIG. 6, a source-side epitaxial growth layer 126a and a drain-side epitaxial growth layer 126b may be formed in the source-side recess region 125a and the drain-side recess region 125b, respectively. For example, the epitaxial growth layers 126a and 126b may be formed using a selective epitaxial growth (SEG) technique employing the impurity regions 121a and 121b as seed layers. The epitaxial growth layers 126a and 126b may be formed of a semiconductor layer having a different lattice constant from the semiconductor substrate. For example, if the semiconductor substrate 100 is a silicon substrate, the epitaxial growth layers 126a and 126b may be formed of SiGe layers. In this case, the epitaxial growth layers 126a and 126b may exhibit compressive stress with respect to the channel region between the first and second impurity regions 121a and 121b, which may convert the channel region into a strained channel.

In an example embodiment, the source-side epitaxial growth layer 126a may include first and second epitaxial growth portions 126a′ and 126a″ that may fill the first and second recess regions (122a and 124a of FIG. 5), respectively, in the first impurity region 121a. Similarly, the drain-side epitaxial growth layer 126b may be include first and second epitaxial growth portions 126b′ and 126b″ that may fill the first and second recess regions (122b and 124b of FIG. 5), respectively, in the second impurity region 121b. In this case, crystal defects D may be generated in the epitaxial growth layers 126a and 126b, for example, in the second epitaxial growth portions 126a″ and 126b″. This is because discontinuous crystalline structures may be formed at interfaces between the portions of the epitaxial growth layers that are laterally and vertically grown on sidewalls and bottoms of the second recess regions 124a and 124b when the epitaxial growth layers 126a and 126b are formed. According to an example embodiment, the crystal defects D in the epitaxial growth layers 126a and 126b may not directly affect the junction leakage current characteristics of the first and second impurity regions 121a and 121b. This is because the epitaxial growth layers 126a and 126b may be formed in the first and second impurity regions 121a and 121b and the crystal defects D may be spaced apart from the junctions of the first and second impurity regions 121a and 121b.

In addition, according to an example embodiment, each of the epitaxial growth layers 126a and 126b may include the first epitaxial growth portions 126a′ or 126b′, which may be adjacent to the channel region, and the second epitaxial growth portions 126a″ or 126b″, which may be deeper than the first epitaxial growth portions 126a′ or 126b′. Therefore, the strained effect in the channel region may be increased.

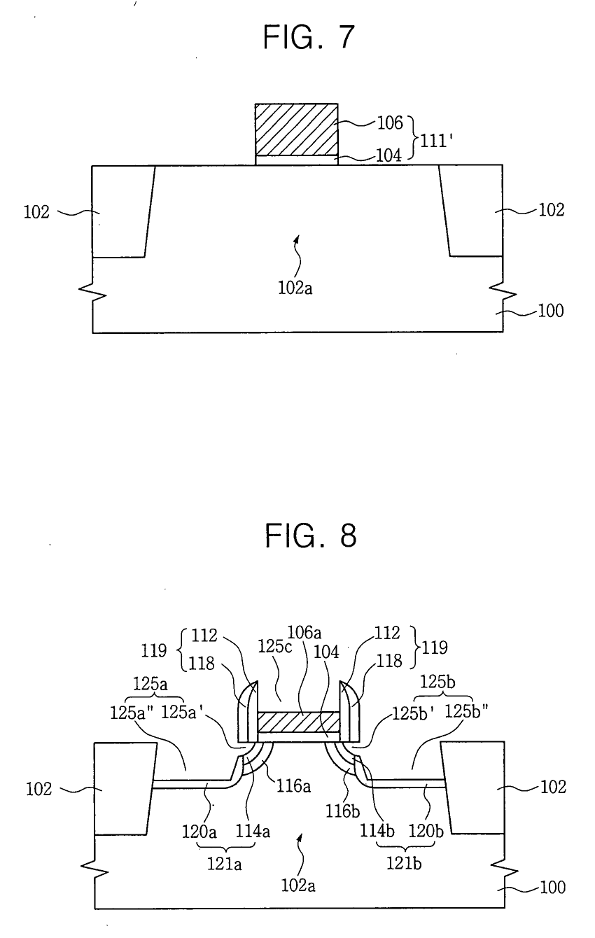

FIGS. 7 to 9 are cross-sectional views illustrating a method of fabricating an MOS transistor according to another example embodiment.

Referring to FIG. 7, an insulating region 102 may be formed in a predetermined (or, alternatively, a desired) region of a semiconductor substrate 100 to define an active region 102a using the method as described with reference to FIG. 1. A gate pattern 111′ may be formed over the active region 102a. The gate pattern 111′ may be formed by sequentially stacking a gate insulating layer (not shown) and a gate conductive layer (not shown) on the active region 102a, and successively patterning the gate conductive layer and the gate insulating layer. Accordingly, the gate pattern 111′ may include a gate insulating layer pattern 104 and a gate electrode 106, which may be sequentially stacked.

Referring to FIG. 8, a source-side recess region 125a, a drain-side recess region 125b, and first and second impurity regions 121a and 121b may be formed in the active region 102a using the method as described with reference to FIGS. 2 to 5. If the gate electrode 106 is formed of the same material layer (e.g., a silicon layer) as the semiconductor substrate 100, the gate electrode 106 may be etched during formation of the recess regions 125a and 125b. As a result, a gate recess region 125c may be formed over the gate insulating layer pattern 104. A portion of the gate electrode 106 (e.g., a gate electrode residue 106a) may remain on the gate insulating layer pattern 104 after formation of the recess regions 125a and 125b. For example, the gate electrode 106 may be formed to a sufficient thickness so that the gate electrode 106 may not be completely removed during formation of the recess regions 125a and 125b.

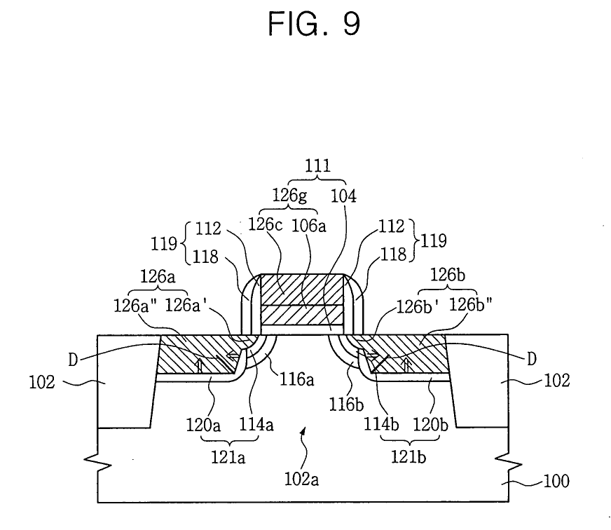

Referring to FIG. 9, a source-side epitaxial growth layer 126a and a drain-side epitaxial growth layer 126b filling the source-side recess region 125a and the drain-side recess region 125b, respectively, may be formed using the method as described with reference to FIG. 6. In an example embodiment, the gate recess region 125c may be filled with a gate semiconductor layer 126c during formation of the epitaxial growth layers 126a and 126b. Accordingly, the gate semiconductor layer 126c may be the same material layer as the epitaxial growth layers 126a and 126b. The gate electrode residue 106a and the gate semiconductor layer 126c may constitute a gate electrode 126g, and the gate electrode 126g and the gate insulating layer pattern 104 may constitute a gate pattern 111.

FIGS. 6 and 9 illustrate semiconductor devices, according to example embodiments.

Referring again to FIG. 6, an insulating region 102 may be provided in a predetermined (or, alternatively, a desired) region of a semiconductor substrate 100 to define an active region 102a. For example, the semiconductor substrate may be a silicon substrate. A gate pattern 110 may be disposed over the active region 102a. A spacer 119 may be provided on a sidewall of the gate pattern 110. The spacer 119 may include a first spacer 112 disposed on the sidewall of the gate pattern 110, and a second spacer 118 disposed on an outer sidewall of the first spacer 112. First and second impurity regions 121a and 121b may be provided on opposite sides of the gate pattern 110, and may define a channel region under the gate pattern 110.

The first impurity region 121a may include a first lower-concentration impurity region 114a and a first higher-concentration impurity region 120a, and the first lower-concentration impurity region 114a may be disposed below the spacer 119. Similarly, the second impurity region 121b may include a second lower-concentration impurity region 114b and a second higher-concentration impurity region 120b, and the second lower-concentration impurity region 114b may also be disposed below the spacer 119. The higher-concentration impurity regions 120a and 120b may be deeper than the lower-concentration impurity regions 114a and 114b. The first and second impurity regions 121a and 121b may have a different conductivity type from the semiconductor substrate 100.

The first and second lower-concentration impurity regions 114a and 114b may be surrounded by first and second halo regions 116a and 116b, respectively. The halo regions 116a and 116b may have the same conductivity type as the semiconductor substrate 100.

A source-side epitaxial growth layer 126a may be provided in the first impurity region 121a, and a drain-side epitaxial growth layer 126b may be provided in the second impurity region 121b. The epitaxial growth layers 126a and 126b may be semiconductor layers having a different lattice constant from the semiconductor substrate 100. For example, if the semiconductor substrate 100 is a silicon substrate, the epitaxial growth layers 126a and 126b may be silicon-germanium layers.

The source-side epitaxial growth layer 126a may include a first epitaxial growth portion 126a′ on the first lower-concentration impurity region 114a and a second epitaxial growth portion 126a″ on the first higher-concentration impurity region 120a. Similarly, the drain-side epitaxial growth layer 126b may include a first epitaxial growth portion 126b′ in the second lower-concentration impurity region 114b and a second epitaxial growth layer 126b″ in the second higher-concentration impurity region 120b. The second epitaxial growth portions 126a″ and 126b″ may be deeper than the first epitaxial growth portions 126a′ and 126b′.

According to an example embodiment, first epitaxial growth portions 126a′ and 126b′ may be provided adjacent to a channel region, and second epitaxial growth portions 126a″ and 126b″ may be provided deeper than the first epitaxial growth portions 126a′ and 126b′. The first and second epitaxial growth portions 126a′, 126b′, 126a″ and 126b″ may be formed of semiconductor layers having a different lattice constant from the semiconductor substrate 100. As a result, the epitaxial growth portions 126a′, 126b′, 126a″ and 126b″ may apply stress to the channel region, which may increase a strained effect in the channel region.

A semiconductor device according to an example embodiment as shown in FIG. 9 may have a different gate pattern structure from a semiconductor device according to an example embodiment as shown in FIG. 6. The gate pattern 110 of the semiconductor device illustrated in FIG. 6 may include a gate insulating pattern 104, a gate electrode 106, and a gate capping insulating pattern 108, which may be sequentially stacked; whereas the gate pattern 111 of the semiconductor device illustrated in FIG. 9 may include only a gate insulating pattern 104 and a gate electrode 126g, which may be sequentially stacked. It will be apparent to one of ordinary skill in the art that the semiconductor device according to an example embodiment as shown in FIG. 9 may exhibit the same effect as a semiconductor device according to an example embodiment as shown in FIG. 6.

Example embodiments may include an epitaxial growth layer formed on an impurity region, and the epitaxial growth layer may include a first epitaxial growth layer extending adjacent to a gate pattern and a second epitaxial growth layer which may be deeper than the first epitaxial growth layer. Therefore, a channel strained effect can be increased without deterioration of junction leakage current characteristics.

While example embodiments have been particularly shown and described, it will be understood by those skilled in the art that various changes in form and details may be made therein without departing from their spirit and scope.

What is claimed is:

1. A semiconductor device comprising:
a gate pattern formed on a semiconductor substrate;
at least one impurity region formed in the semiconductor substrate such that at least a portion of the impurity region is disposed under the gate pattern; and
an epitaxial growth layer formed on the at least one impurity region, the epitaxial growth layer including a first epitaxial growth portion spaced apart from the gate pattern and a second epitaxial growth portion extending toward the gate pattern from the first epitaxial growth portion.

2. The semiconductor device according to claim 1, wherein the second epitaxial growth portion is formed having a depth smaller than the depth of the first epitaxial growth portion.

3. The semiconductor device according to claim 2, wherein the first epitaxial growth portion has a depth of 500 to 700 Å from a surface of the semiconductor substrate.

4. The semiconductor device according to claim 3, wherein the second epitaxial growth portion has a depth of 100 to 300 Å from a surface of the semiconductor substrate

5. The semiconductor device according to claim 2, wherein the second epitaxial growth portion has a depth of 100 to 300 Å from a surface of the semiconductor substrate

6. The semiconductor device according to claim 1, wherein the epitaxial growth layer is a semiconductor layer having a different lattice constant than the semiconductor substrate.

7. The semiconductor device according to claim 6, wherein the epitaxial growth layer includes silicon-germanium (SiGe).

8. The semiconductor device according to claim 1, wherein the gate pattern comprises:
a gate insulating pattern formed on the semiconductor substrate;
a gate electrode formed on the gate insulating pattern; and
a gate capping insulating pattern formed on the gate electrode.

9. The semiconductor device according to claim 1, wherein the gate pattern comprises:
a gate insulating pattern formed on the semiconductor substrate; and
a gate electrode formed on the gate insulating pattern.

10. The semiconductor device according to claim 1, further comprising:
a spacer disposed on a sidewall of the gate pattern; and wherein
the second epitaxial growth portion is disposed below the spacer.

11. The semiconductor device according to claim 10, wherein the spacer comprises:
a first spacer disposed on a sidewall of the gate pattern; and
a second spacer covering an outer sidewall of the first spacer.

12. The semiconductor device according to claim 10, wherein at least a portion of the impurity region and the second epitaxial growth portion are disposed under the spacer, and the first epitaxial growth portion is disposed outward of the spacer.

13. The semiconductor device according to claim 1, wherein the at least one impurity region comprises:
a higher-concentration impurity region spaced apart from the gate pattern; and
a lower-concentration impurity region extending toward the gate pattern from the higher-concentration impurity region, and the lower-concentration impurity region having a lower concentration than the higher-concentration impurity region.

14. The semiconductor device according to claim 13, further comprising:
a halo region surrounding the lower-concentration impurity region, the halo region being doped with impurities having a same conductivity type as the semiconductor substrate.

15. A method of fabricating a semiconductor device, comprising:
forming a gate pattern on a semiconductor substrate;
forming a spacer on a sidewall of the gate pattern;
forming at least one impurity region in the semiconductor substrate adjacent to the spacer;
isotropically etching the impurity region to form a first recess region in the impurity region extending below the spacer;
anisotropically etching the impurity region using the spacer and the gate pattern as etch masks to form a second recess region in the impurity region; and
forming an epitaxial growth layer filling the first and second recess regions.

16. The method according to claim 15, wherein forming the gate pattern comprises:
forming a gate insulating layer on the semiconductor substrate;
forming a gate conductive layer on the gate insulating layer; and
patterning the gate conductive layer and the gate insulating layer; and wherein
the patterned gate conductive layer is etched during at least one of the isotropic etching and anisotropic etching processes to provide a gate recess region, and the gate recess region is filled with a same material used to form the epitaxial growth layer during formation of the epitaxial growth layer.

17. The method according to claim 15, wherein forming the gate pattern comprises:
forming a gate insulating layer on the semiconductor substrate;
forming a gate conductive layer on the gate insulating layer;
forming a capping insulating layer on the gate conductive layer; and
patterning the capping insulating layer, the gate conductive layer and the gate insulating layer.

18. The method according to claim 15, wherein forming the spacer comprises:
forming a first spacer on a sidewall of the gate pattern; and
forming a second spacer on an outer sidewall of the first spacer.

19. The method according to claim 15, wherein forming the impurity region includes:
forming a lower-concentration impurity region by implanting impurity ions into the semiconductor substrate using the gate pattern as an ion implantation mask; and
forming a higher-concentration impurity region by implanting impurity ions into the semiconductor substrate using the gate pattern and the spacer as ion implantation mask, the higher-concentration impurity region having a higher impurity concentration than the lower-concentration impurity region.

20. The method according to claim 19, further comprising:
forming a halo region surrounding the lower concentration-impurity region by applying a tilted ion implantation process into the semiconductor substrate under at least one edge of the gate pattern, the halo regions having the same conductivity type as the semiconductor substrate.

21. The method according to claim 15, wherein the second recess region is formed having a depth greater than the first recess region.

22. The method according to claim 20, wherein the first recess region is formed to a depth of 100 to 300 Å.

23. The method according to claim 22, wherein the second recess region is formed to a depth of 500 to 700 Å.

24. The method according to claim 20, wherein the second recess region is formed to a depth of 500 to 700 Å.

25. The method according to claim 15, wherein the epitaxial growth layer is formed of a semiconductor layer having a different lattice constant than the semiconductor substrate.

26. The method according to claim 25, wherein the epitaxial growth layer includes silicon-germanium (SiGe).

27. The method according to claim 15, wherein the isotropically etching and the anisotropically etching of the impurity region to form the first and second recess regions in the impurity region do not completely remove the impurity region.

28. A method of fabricating a semiconductor device, comprising:
forming a gate pattern on a substrate;
forming an impurity region in the substrate;
etching the impurity region to create a first recess and a second recess, the second recess being deeper than the first recess and further from the gate pattern than the first recess; and
filling the first and second recesses with an epitaxial layer.

29. A semiconductor device, comprising:
a gate pattern formed on a substrate;
an epitaxial layer formed in the substrate, the epitaxial layer including,
a first epitaxial portion formed in the substrate to a first depth, and
a second epitaxial portion formed in the substrate to a second depth that is deeper than the first depth, the first epitaxial portion being closer to the gate pattern than the second epitaxial portion; and
impurity regions formed under the first and second epitaxial portions.
